(19) United States
(12) Patent Application Publication
(10) Pub. No.: US 2008/0173237 A1
(43) Pub. Date: Jul. 24, 2008

(54) Plasma Immersion Chamber

(76) Inventors: Kenneth S. Collins, San Jose, CA (US); Andrew N. Nguyen, San Jose, CA (US); Kartik Ramaswamy, San Jose, CA (US); Hiroji Hanawa, Sunnyvale, CA (US); Douglas A. Buchberger, Livermore, CA (US); Daniel J. Hoffman, Saratoga, CA (US); Amir Al-Bayati, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/016,810

(22) Filed: Jan. 18, 2008

Related U.S. Application Data
(60) Provisional application No. 60/885,790, filed on Jan. 19, 2007.
(60) Provisional application No. 60/885,808, filed on Jan. 19, 2007.
(60) Provisional application No. 60/885,861, filed on Jan. 19, 2007.
(60) Provisional application No. 60/885,797, filed on Jan. 19, 2007.

(51) Int. Cl. C23C 16/453

(52) U.S. Cl. 118/723 I; 118/723 R

(57) ABSTRACT

Embodiments described herein generally provide a toroidal plasma source, a plasma channeling device, a showerhead, and a substrate support assembly for use in a plasma chamber. The toroidal plasma source, plasma channeling device, showerhead, and substrate support assembly are adapted to improve the usable lifetime of the plasma chamber, as well as reduce assembly cost, increase the plasma chamber reliability, and improve device yield on the processed substrates.

### CROSS-REFERENCE TO RELATED APPLICATIONS

This application claims benefit of U.S. Provisional Patent Application Ser. No. 60/885,790 (Attorney Docket No. 11791L), filed Jan. 19, 2007, U.S. Provisional Patent Application Ser. No. 60/885,808 (Attorney Docket No. 11792L), filed Jan. 19, 2007, U.S. Provisional Patent Application Ser. No. 60/885,861 (Attorney Docket No. 11793L), filed Jan. 19, 2007, U.S. Provisional Patent Application Ser. No. 60/885,797 (Attorney Docket No. 11795L), filed Jan. 19, 2007, each of which are incorporated by reference herein in their entireties.

### BACKGROUND OF THE INVENTION

1. Field of the Invention

Embodiments of the present invention generally relate to a processing a substrate, such as a semiconductor wafer, in a plasma process. More particularly, to a plasma process for depositing materials on a substrate or removing materials from a substrate, such as a semiconductor wafer.

2. Description of the Related Art

Integrated circuits that are formed on substrates, such as semiconductor wafers, may include more than one million micro-electronic field effect transistors (e.g., complementary metal-oxide-semiconductor (CMOS) field effect transistors) and cooperate to perform various functions within the circuit. A CMOS transistor typically includes a gate structure disposed between source and drain regions that are formed in the substrate. The gate structure generally includes a gate electrode and a gate dielectric layer. The gate electrode is disposed over the gate dielectric layer to control a flow of charge carriers in a channel region formed between the drain and source regions beneath the gate dielectric layer.

An ion implantation process is typically utilized to dope a desired material a desired depth into a surface of a substrate to form the gate and source drain structures within a device formed on the substrate. During an ion implantation process, different process gases or gas mixtures may be used to provide a source for the dopant species. As the process gases are supplied into the ion implantation processing chamber, a RF power may be generated to produce a plasma to promote ionization of the process gases, and the acceleration of the plasma generated ions toward and into the surface of the substrate as described in U.S. Pat. No. 7,037,813, which issued May 2, 2006.

One plasma source used to promote dissociation of the process gases includes a toroidal source, which includes at least one hollow tube or conduit coupled to a process gas source and two openings formed in and coupled to a portion of the chamber. The hollow tube couples to openings formed in the chamber and the interior of the hollow tube forms a portion of a path that, when energized, produces a plasma that circulates through the interior of the hollow tube and a processing zone within the chamber.

The effectiveness of a substrate fabrication process is often measured by two related and important factors, which are device yield and the cost of ownership (CoO). These factors are important since they directly affect the cost to produce an electronic device and thus a device manufacturer's competitiveness in the market place. The CoO, while affected by a number of factors, is greatly affected by the reliability of the various components used to process a substrate, the lifetime of the various components, and the piece part cost of each of the components. Thus, one key element of CoO is the cost of the “consumable” components, or components that have to be replaced during the lifetime of the processing device due to damage, wear or aging during processing. In an effort to reduce CoO, electronic device manufacturers often spend a large amount of time trying to increase the lifetime of the “consumable” components and/or reduce the number of components that are consumable.

Other important factors in the CoO calculation are the reliability and system uptime. These factors are very important for determining a processing device's profitability and/or usefulness, since the longer the system is unable to process substrates, the more money is lost by the user due to the lost opportunity to process substrates in the tool. Therefore, cluster tool users and manufacturers spend a large amount of time trying to develop reliable processes and reliable hardware that have increased uptime.

Therefore, there is a need for an apparatus that can perform a plasma process which can meet the required device performance goals and minimizes the CoO associated with forming a device using the plasma process.

### SUMMARY OF THE INVENTION

Embodiments described herein relate to robust elements for a plasma chamber. In one embodiment, a toroidal plasma source is described. The toroidal plasma source includes a first hollow conduit comprising a U shape and a rectangular cross-section, a second hollow conduit comprising an M shape and a rectangular cross-section, an opening disposed at opposing ends of each of the first and second hollow conduits, and a coating disposed on an interior surface of each of the first and second hollow conduits.

In another embodiment, a plasma channeling apparatus is described. The plasma channeling apparatus includes a body having at least two channels disposed longitudinally therethrough, the at least two channels being separated by a wedge-shaped member, and a coolant channel formed at least partially in a sidewall of the body.

In another embodiment, a gas distribution plate is described. The gas distribution plate includes a circular member having a first side and a second side, a recessed portion formed in a central region of the first side to form an edge along a portion of the first side of the circular member, wherein the recessed portion includes a plurality of orifices that extend from the first side to the second side, and a mounting portion coupled to a perimeter of the circular member and extending radially therefrom.

In another embodiment, a cathode assembly for a substrate support is described. The cathode assembly includes a body having a conductive upper layer, a conductive lower layer, and a dielectric material electrically separating the upper layer and the lower layer, wherein at least one opening is formed longitudinally through the body, and one or more dielectric fillers disposed at locations within the body selected from the group consisting of: a first interface between the dielectric material and the upper layer; and a second interface between the dielectric material and the lower layer, and combinations thereof.

In another embodiment, an electrostatic chuck for supporting a substrate is described. The electrostatic chuck includes a puck having a diameter approximating that of the substrate, a metal layer coupled to the puck, a chucking electrode buried in the puck, a cathode base that is in electrical communication with an electrical ground, a support insulator disposed between the cathode base and the metal layer, where in the metal layer is disposed within a valley formed in the support insulator, coolant passages formed in the metal layer, wherein the coolant passages are capable of conducting a coolant medium therethrough for cooling the puck, and a conductor having one end thereof coupled to said puck, and another end thereof for coupling to a source of RF power.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an isometric cross-sectional view of one embodiment of a plasma chamber.

FIG. 2 is an isometric top view of the plasma chamber shown in FIG. 1.

FIG. 3A is a side cross-sectional view of one embodiment of a first reentrant conduit.

FIG. 3B is a side cross-sectional view of one embodiment of a second reentrant conduit.

FIG. 4 is a bottom view of one embodiment of a reentrant conduit.

FIG. 5A is an isometric detail view of one embodiment of a plasma channeling device from FIG. 1.

FIG. 5B is a side, cross-sectional view of one embodiment of the plasma channeling device of FIG. 5A.

FIG. 6 is an isometric view of the plasma channeling device of FIG. 5A.

FIG. 7 is a cross-sectional side view of the plasma channeling device of FIG. 5A.

FIG. 8 is an isometric view of one embodiment of a showerhead.

FIG. 9A is a cross-sectional side view of the showerhead of FIG. 8.

FIG. 9B is an exploded cross-sectional view of a portion of the perforated plate shown in FIG. 9A.

FIG. 10 is an isometric cross-sectional view of one embodiment of a substrate support assembly.

FIG. 11 is a partial cross sectional view of the electrostatic chuck of FIG. 10 having a substrate thereon.

To facilitate understanding, identical reference numerals have been used, where possible, to designate identical elements that are common to the figures. It is also contemplated that elements disclosed in one embodiment may be beneficially utilized on other embodiments without specific recitation.

### DETAILED DESCRIPTION

Embodiments described herein generally provide a robust plasma chamber having parts configured for extended processing time, wherein frequent replacement of the various parts of the chamber is not required. In some embodiments, robust consumable parts or alternatives to consumable parts for a plasma chamber are described, wherein the parts are more reliable and promote extended process lifetimes. In one embodiment, a toroidal plasma chamber is described for performing an ion implantation process on a semiconductor substrate, although certain embodiments described herein may be used on other chambers and/or in other processes.

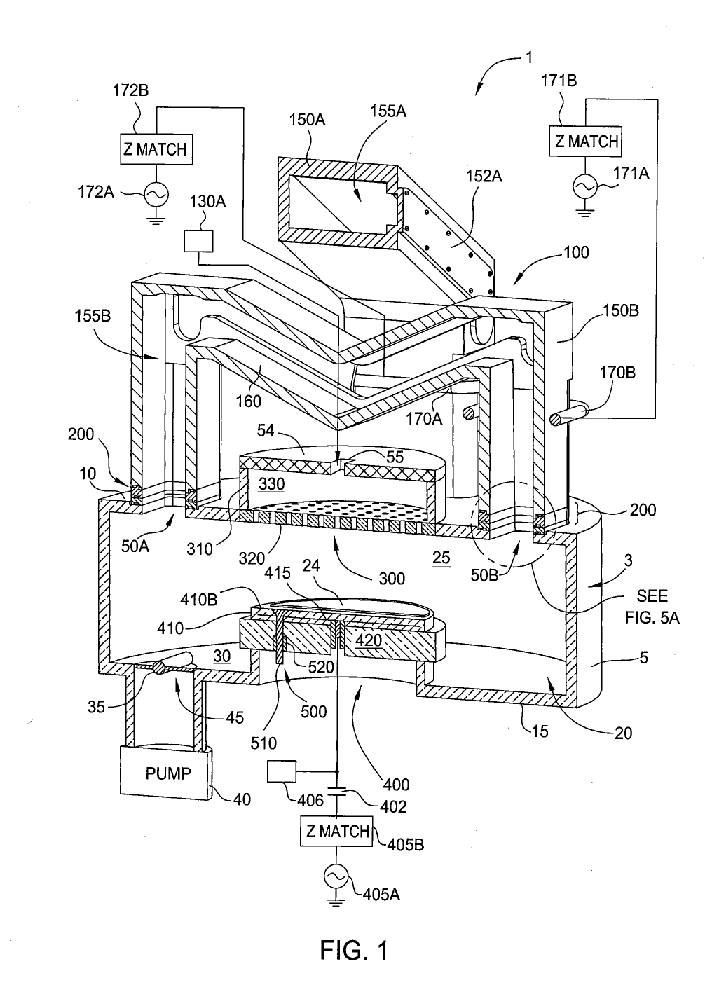

FIG. 1 is an isometric cross-sectional view of one embodiment of a plasma chamber 1 that may be configured for a plasma enhanced chemical vapor deposition (PECVD) process, a high density plasma chemical vapor deposition (HDPCVD) process, an ion implantation process, an etch process, and other plasma processes. The chamber 1 includes a body 3 having sidewalls 5 coupled to a lid 10 and a bottom 15, which bounds an interior volume 20. Other examples of a plasma chamber 1 may be found in U.S. Pat. No. 6,939,434, filed Jun. 5, 2002 and issued on Sep. 6, 2005 and U.S. Pat. No. 6,893,907, filed Feb. 24, 2004 and issued May 17, 2005, both of which are incorporated by reference herein in their entireties.

### Toroidal Plasma Source

The plasma chamber 1 includes a reentrant toroidal plasma source 100 coupled to the body 3 of the chamber 1. The interior volume 20 includes a processing region 25 formed between a gas distribution assembly, also referred to as a showerhead 300, and a substrate support assembly 400, which is configured as an electrostatic chuck. A pumping region 30 surrounds a portion of the substrate support assembly 400. The pumping region 30 is in selective communication with a vacuum pump 40 by a valve 35 disposed in a port 45 formed in the bottom 15. In one embodiment, the valve 35 is a throttle valve that is adapted to control the flow of gas or vapor from the interior volume 20 and through the port 45 to the vacuum pump 40. In one embodiment, the valve 35 operates without the use of o-rings, and is further described in United States Patent Publication No. 2006/0237136, filed Apr. 26, 2005 and published on Oct. 26, 2006, which is incorporated by reference in its entirety.

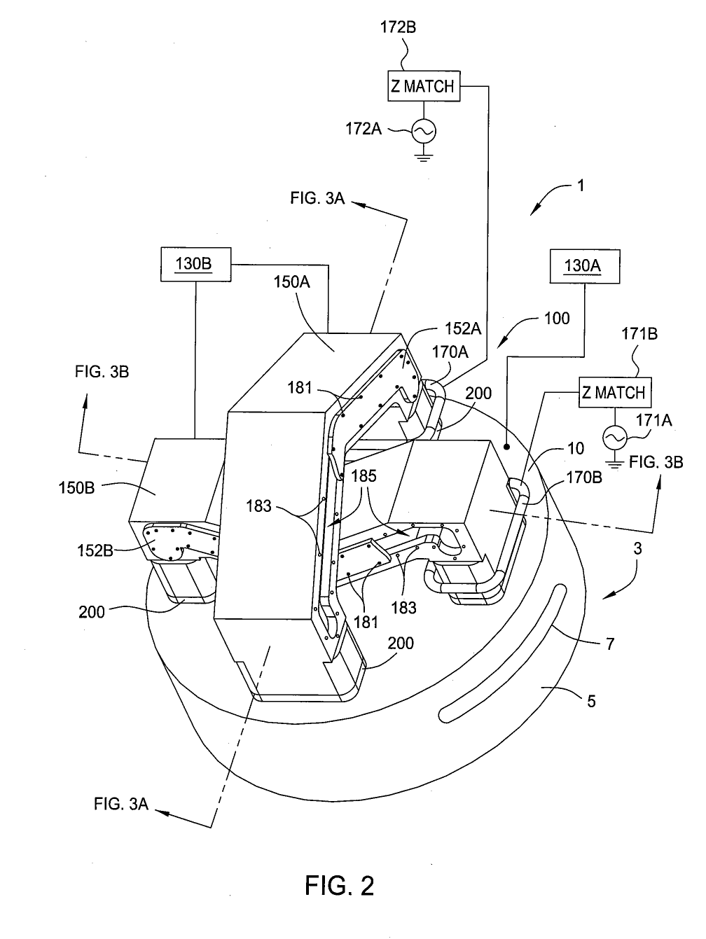

The toroidal plasma source 100 includes a first reentrant conduit 150A having a general “U” shape, and a second reentrant conduit 150B having a general “M” shape. When conduit 150A is coupled to the chamber 1, the general shape of the conduit may be referred to as an upside down capital letter U, and upside down letter V, and combinations thereof. The first reentrant conduit 150A and the second reentrant conduit 150B each include at least one radio frequency (RF) applicator, such as antennas 170A, 170B that are used to form an inductively coupled plasma within an interior region 155A, 155B of each of the conduits 150A, 150B, respectively. Referring to FIGS. 1 and 2, each antenna 170A, 170B may include a magnetically permeable toroidal core surrounding at least a portion of the respective conduits 150A, 150B, a conductive winding or a coil wound around a portion of the core, and an RF power source, such as RF power sources 171A, 172A. RF impedance matching systems 171B, 172B may also be coupled to each antenna 170A, 170B. Process gases, such as hydrogen, helium, nitrogen, argon, and other gases, and/or cleaning gases, such as fluorine containing gases, may be provided to an interior region 155A, 155B of each of the conduits 150A, 150B, respectively. In one embodiment, the process gases may contain a dopant containing gases that are supplied to the interior regions 155A, 155B of each conduit 150A, 150B. In one embodiment, the process gas is delivered from a gas source 130A that is connected to a port 55 formed in the body 3 of the chamber 1, such as in a cover 54 coupled to the showerhead 300, and the process gas is delivered to the processing region 25, which is in communication with the interior regions 155A, 155B of each conduit 150A, 150B.

The gas distribution plate, or showerhead 300, may be coupled to lid 10 in a manner that facilitates replacement and may include seals, such as o-rings (not shown) between the lid 10 and the outer surface of the showerhead 300 to maintain negative pressure in the processing volume 25. The showerhead 300 includes an annular wall 310 defining a plenum 330 between the cover 54 and a perforated plate 320. The perforated plate 320 includes a plurality of openings formed through the plate in a symmetrical or non-symmetrical pattern or patterns. Process gases, such as dopant-containing gases, may be provided to the plenum 330 from the port 55. Generally, the dopant-containing gas is a chemical consisting of the dopant impurity atom, such as boron (a p-type conductivity impurity in silicon) or phosphorus (an n-type conductivity impurity in silicon) and a volatile species such as fluorine and/or hydrogen. Thus, fluorides and/or hydrides of boron, phosphorous, or other dopant species such as, arsenic, antimony, etc., can be dopant gases. For example, where a boron dopant is used, the dopant-containing gas may contain boron trifluoride (BF₃) or diborane (B₂H₆). The gases may flow through the openings and into the processing region 25 below the perforated plate 320. In one embodiment, the perforated plate is RF biased to help generate and/or maintain a plasma in the processing region 25.

In one embodiment, each opposing end of the conduits 150A, 150B are coupled to respective ports 50A-50D (only 50A and 50B are shown in this view) formed in the lid 10 of the chamber 1. In other applications (not shown) the ports 50A-50D may be formed in the sidewall 5 of the chamber 1. The ports 50A-50D are generally disposed orthogonally or at 90° angles relative to one another. During processing a process gas is supplied to the interior region 155A, 155B of each of the conduits 150A, 150B, and RF power is applied to each antenna 170A, 170B, to generate a circulating plasma path that travels through the ports 50A-50D and the processing region 25. Specifically, in FIG. 1, the circulating plasma path travels through port 50A to port 50B, or vise versa, through the processing region 25 between the showerhead 300 and substrate support assembly 400. Each conduit 150A, 150B includes a plasma channeling device 200 coupled between respective ends of the conduit and the ports 50A-50D, which is configured to split and widen the plasma path formed within each of the conduits 150A, 150B. The plasma channeling device 200 (described below) may also include an insulator to provide an electrical break along the conduits 150A, 150B.

The substrate support assembly 400 generally includes an upper layer or puck 410 and a cathode assembly 420. The puck 410 includes a smooth substrate supporting surface 410B and an embedded electrode 415 that can be biased by use of a direct current (DC) power source 406 to facilitate electrostatic attraction between a substrate and the substrate supporting surface 410B of the puck 410. The embedded electrode 415 may also be used as an electrode that provides RF energy to the processing region 25 and form an RF bias during processing. The embedded electrode 415 may be coupled to a RF power source 405A and may also include an impedance match circuit 405B. DC power from power source 406 and RF from power source 405A may be isolated by a capacitor 402. In one embodiment, the substrate support assembly 400 is a substrate contact-cooling electrostatic chuck in which the portion of the chuck contacting the substrate is cooled. The cooling is provided by coolant channels (not shown) disposed in the cathode assembly 420 for circulating a coolant therein.

The substrate support assembly 400 may also include a lift pin assembly 500 that contains a plurality of lift pins 510 (only one is shown in this view). The lift pins 510 facilitate transfer of one or more substrates by selectively lifting and supporting a substrate above the puck 410, and are spaced to allow a robot blade (not shown) to be positioned therebetween. The lift pin assemblies 500 contain lift pin guides 520 that are coupled to one or both of the puck 410 and the cathode assembly 420.

FIG. 2 is an isometric top view of the plasma chamber 1 shown in FIG. 1. The sidewall 5 of the chamber 1 includes a wafer port 7 that may be selectively sealed by a slit valve (not shown). Process gases are supplied to the showerhead 300 by process gas source 130A through port 55 (FIG. 1). Process and/or cleaning gases may be supplied to the conduits 150A, 150B by gas source 130B.

In one embodiment, the first reentrant conduit 150A comprises a hollow conduit having the general shape of a “U” and the second reentrant conduit 150B comprises a hollow conduit having the general shape of an “M”. The conduits 150A, 150B may be made of a conductive material, such as sheet metal, and may comprise a cross-section that is circular, oval, triangular, or rectangular shaped. The conduits 150A, 150B also include a slot 185 formed in a sidewall that may be enclosed by the cover 152A for conduit 150A and cover 152B for conduit 150B. The sidewall of each conduit 150A, 150B also includes holes 183 adapted to receive fasteners 181, such as screws, bolts, or other fastener, that are adapted to attach the covers to the respective conduit. The slot 185 is configured for access to the interior region 155A, 155B of each conduit 150A, 150B, for cleaning and/or refurbishing, for example, to apply a coating 160 (FIG. 1) to the interior region 155A, 155B of each conduit 150A, 150B. In one embodiment, each of the conduits 150A, 150B are made from an aluminum material, and the coating 160 comprises an anodized coating. In another embodiment, the coating 160 may include a yttrium material, for example yttrium oxide (Y₂O₃).

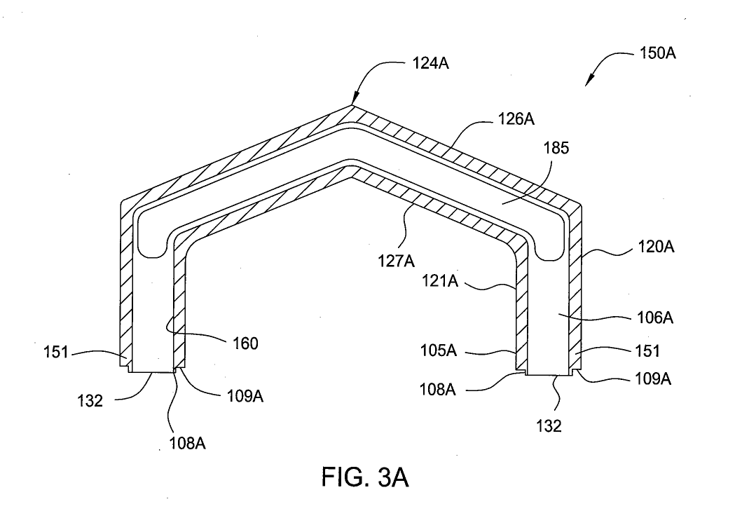

FIG. 3A is a side cross-sectional view of one embodiment of a first reentrant conduit or “U” shaped conduit 150A. The conduit 150A includes a hollow housing 105A that includes sidewalls that form a general “U” shape. The conduit 150A is generally symmetrical and includes a first sidewall 120A opposing a second sidewall 121A that is shorter in length than the first sidewall 120A. The first sidewall 120A is coupled to an angled top sidewall 126A at an angle greater than 90 degrees, such as between about 100 degrees and about 130 degrees. An angled bottom sidewall 127A is opposing and substantially parallel to the angled top sidewall 126A. Each of the angled bottom sidewall 127A and angled top sidewall 126A meet at an apex 124A. The slot 185 may include a general “U” shape and may be formed through the body 105 in a rear sidewall 106A. The slot 185 may extend at least partially into the area between the first sidewall 120A and second sidewall 121A, and between the angled top sidewall 126A and angled bottom sidewall 127A. The conduit 150A also includes two openings 132 at opposing ends of the hollow housing 105A that is adapted to couple to the lid 10 and/or the plasma channeling device 200 (both shown in FIG. 1). The sidewalls 120A, 121A, and rear sidewall 106A include a recessed area 109A near each opening 132 that defines a shoulder 108A bounding each opening 132.

FIG. 3B is a side cross-sectional view of one embodiment of a second reentrant conduit or “M” shaped conduit. 150B. The conduit 150B includes a hollow housing 105B that includes sidewalls that form a general “M” shape. The conduit 150B is generally symmetrical and includes a first sidewall 120B opposing a second sidewall 121B that is shorter in length than the first sidewall 120B. The first sidewall 120B is coupled to a flat portion 122 at an angle of about 90 degrees. A top sidewall 126B is coupled to the flat portion 122 at an angle between about 12° to about 22°, and is substantially parallel to a bottom sidewall 127B. In one embodiment, the top sidewall 126B and the bottom sidewall 127B are substantially the same length. The top sidewall 126B and the bottom sidewall 127B meet at a valley 124B in the approximate center of the hollow housing 105B. The slot 185 may include a general “M” shape and may be formed through the body 105 in a rear sidewall 106B. The slot 185 may extend at least partially into the area between the first sidewall 120B and second sidewall 121B, and between the top sidewall 126B and bottom sidewall 127B. The conduit 150B also includes two openings 132 at opposing ends of the hollow housing 105B that are adapted to couple to the lid 10 and/or the plasma channeling device 200 (both shown in FIG. 1). The sidewalls 120B, 121B, and rear sidewall 106B include a recessed area 109B near each opening 132 that defines a shoulder 108B bounding each opening 132.

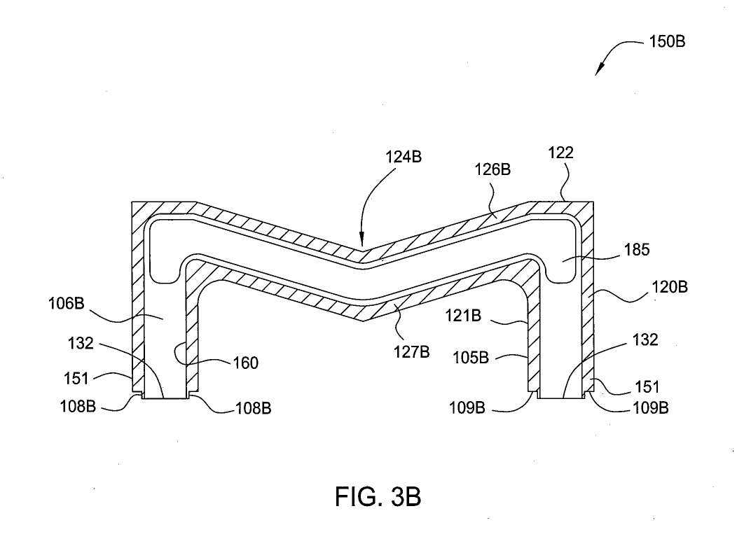

FIG. 4 is a bottom view of one embodiment of a conduit 150C, which represents a bottom view of the first conduit 150A or the second conduit 150B as described herein. A bottom sidewall 127C represents the bottom sidewall 127A of first conduit 150A (FIG. 3A) or the bottom sidewall 127B of second conduit 150B (FIG. 3B), and shoulder 108C represents shoulders 108A or 108B of the first conduit 150A and second conduit 150B. Region 124C (shown as a dashed line) represents the apex 124A of first conduit 150A or valley 124B of second conduit 150B. In this embodiment, each opening 132 comprises a rectangular shape, which includes a length D₁ and a width D₂, and are separated by a distance dimension D₃.

Length D₁ and width D₂ may be correlated or proportional to the distance dimension D₃, and may be mathematically expressed, such as in a ratio or equation. In one embodiment, distance dimension D₃ is greater than the diameter of the substrate. For example, distance dimension D₃ may be about 400 mm to about 550 mm in the case of a 300 mm wafer. In one embodiment, length D₁ is about 130 mm to about 145 mm, and width D₂ is about 45 mm to about 55 mm, while distance dimension D₃ is about 410 mm to about 425 mm in the case of a 300 mm wafer. Each conduit 150A, 150B is proportioned to enable a plasma path therein that is substantially equal. To facilitate the equalized plasma path, the angles of one or both of the apex 124A of conduit 150A and the valley 124B of conduit 150B may be adjusted to equalize the centerline of the interior region 155A of conduit 150A and interior region 155B of conduit 150B. Thus, equalization of the interior regions 155A, 155B of the conduits 150A, 150B provides a substantially equalized plasma path between both conduits 150A, 150B.

### Plasma Channeling Device

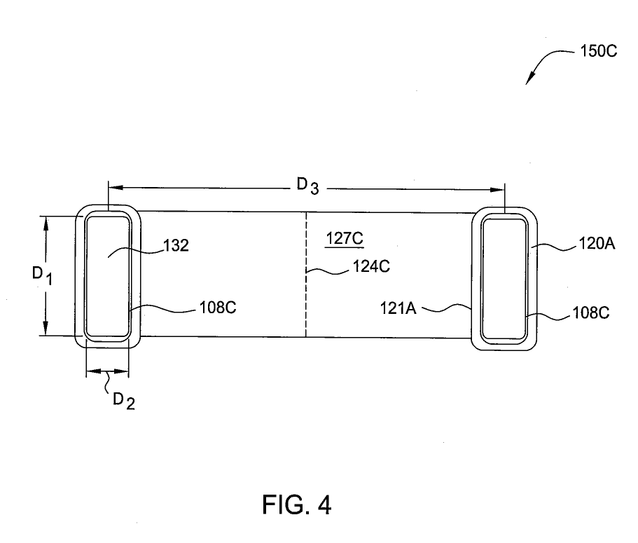

FIG. 5A is an isometric detail view of the plasma channeling device 200 from FIG. 1. The plasma channeling device 200 operates to spread the plasma current from the interior regions 155A, 155B of the conduits 150A, 150B evenly over the surface of the processing region 25 and the surface of the substrate. In one embodiment, the plasma channeling device 200 functions as a transitional member between the conduits 150A, 150B and the ports 50A-50D (only port 50B is shown in this view) to increase the area of the plasma traveling through conduits 150A, 150B. The plasma channeling device 200 operates to broaden the plasma current travelling through conduits 150A, 150B to better cover a wide process area as it exits a port (50B as shown in this view) and minimizes or eliminates “hot spots” or areas of very high ion density at or near an opening.

FIG. 5B is a side, cross-sectional view of one embodiment of a plasma channeling device 200. The plasma channeling device 200 includes a first end 272 adapted to couple to a conduit (not shown in this view) and a second end 274 adapted to be coupled to lid 10 in ports 50A-50D. The plasma channeling device 200 provides a widened plasma path to the processing region 25 by enlarging the area, at least in one dimension, between the first end 272 and the second end 274 to cover a wider area in the processing region 25. For example, length D₁ may be the dimension of the conduit 150C (FIG. 4) and length D₄ is substantially greater than length D₁. In one example, length D₁ may be about 130 mm to about 145 mm while length D₄ may be about 185 mm to about 220 mm in the case of a 300 mm wafer. The plasma channeling device 200 also includes a wedge shaped member 220, which “splits” and “narrows” the plasma current P as the plasma current flows therein. The plasma channeling device 200 therefore operates to control the spatial density of the plasma circulating through conduits 150A, 150B to enable a greater radial plasma distribution in the processing region 25. Further, the wedge shaped member 220 and widened plasma path eliminates or minimizes areas of high ion density at or near the openings in the lid 10. An example of a plasma channeling device that functions to split and/or channel reentering plasma current from or to reentrant conduits as it circulates through a chamber is described in United States Patent Publication No. 2003/0226641, filed Jun. 5, 2002 and published Dec. 11, 2003, which is incorporated by reference in its entirety.

Referring again to FIG. 5A, the plasma channeling device 200 includes a body 210 that includes a generally rectangular cross-sectional shape that generally matches the cross-sectional shape of the port 50B in the lid 10, and an end 151 of the conduit 150B to facilitate coupling therebetween. The body 210 includes an interior surface 236 that may have a coating 237 thereon. In one embodiment, the body 210 is made of a conductive metal, such as aluminum, and the coating 237 may be a yttrium material, for example yttrium oxide (Y₂O₃). The interior surface 236 includes a tapered portion 230 at the first end 272, which may be a radius, a chamfer, or some angled portion formed in the body 210. The first end 272 of the body 210 is adapted to interface with the end 151 of the conduit 150B, and the second end 274 may extend in or through the port 50B in the lid 10. In this view, a length D₅ is shown, which may be substantially equal to length D₂ as described in FIG. 4.

The body 210 includes o-ring grooves 222 that may include o-rings that interface with the end 151 of the conduit 150B and an insulator 280 between the lid 10 and the body 210. The insulator 280 is made of an insulative material, such as polycarbonate, acrylic, ceramics, and the like. The body 210 also includes a coolant channel 228 formed in at least one sidewall for flowing a cooling fluid. The first end 272 of the body also includes a recessed portion 252 in a portion of the interior surface 236 that is adapted to mate with a shoulder 152 formed on the end 151 of the conduit 150B. The shoulder 152 may extend the life of the o-ring as it functions to partially shield the o-ring from plasma.

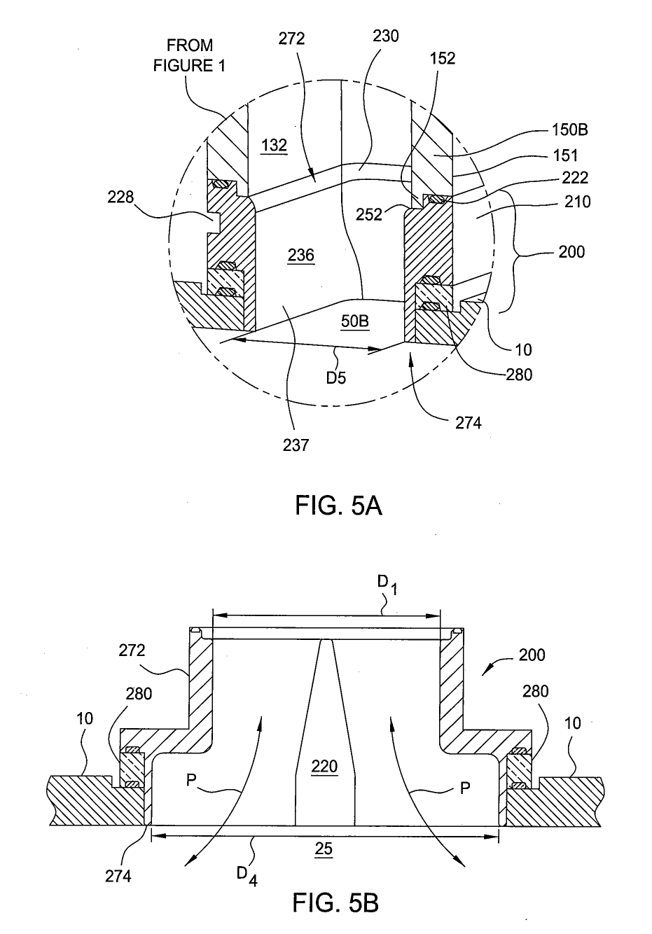

FIG. 6 is an isometric view of the body 210 of the plasma channeling device 200. The body 210 includes four upper sidewalls 205A-205D coupled to a flange portion 215. At least one of the upper sidewalls, shown in this Figure as 205D, includes the coolant channel 228. The coolant channel 228 also includes an inlet port 260 and an outlet port 261. The body 210 also includes four lower sidewalls 244A-244D (only 244A and 244D are shown in this view) at the second end 274. The upper and lower sidewalls may include rounded corners 206 and/or beveled corners 207 between adjoining sidewalls.

In one embodiment, upper sidewalls 205D and 205B intersect with the portion of the flange portion 215 therebetween and share the same plane, and two of the lower sidewalls 244A and opposing lower sidewall 244C extend inwardly or are offset inwardly from the flange portion 215. The flange portion 215 extends beyond a plane of both of the upper sidewalls 205A, 205C and the plane of the lower sidewalls 244A, 244C.

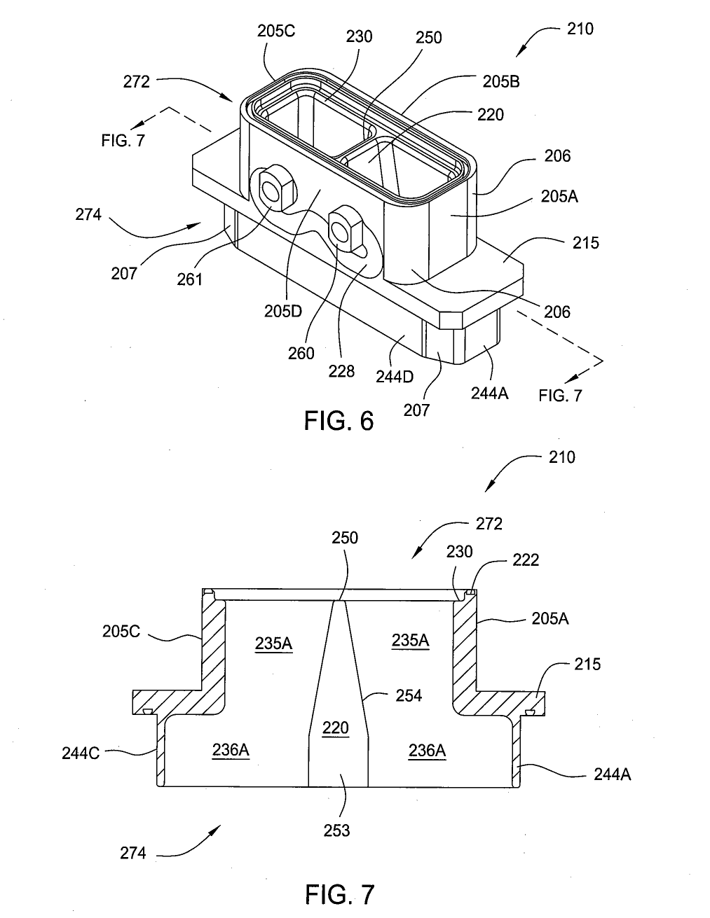

FIG. 7 is a cross-sectional side view of a body 210 of the plasma channeling device 200. A wedge-shaped member 220 divides the interior of the body 210 into two discrete regions. The wedge-shaped member 220 separates two first ports 235A and two second ports 236A, and the area or volume of each of the second ports 236A is larger than the area or volume of each of the first ports 235A. In one embodiment, each of the second ports 236A include an area or volume that is greater than about ⅓ to about ½ of the area or volume of the first ports 235A. Collectively, the first ports 235A and second ports 236A define two channels within the interior of the body 210 that include an expanding area or volume from the first end 272 to the second end 274.

The wedge-shaped member 220 includes a substantially triangular-shaped body having at least one sloped side 254 in cross-section extending from an apex or first end 250 to a base or second end 253. The sloped side 254 may extend from the first end 250 to the second end 253, or the sloped side 254 may intersect with a flat portion along the length of the wedge-shaped member 220 as shown. The first end 250 may include a rounded, angled, flattened, or relatively sharp intersection. The wedge shaped member 220 may be made of an aluminum or ceramic material, and may additionally include a coating, such as a yttrium material.

In operation, the plasma current may enter the first end 272 of the body 210 and exit the second end 274 of the body 210, or vice-versa. Depending on the direction of travel, the plasma current may be widened or broadened as it passes through and out of the second ports 236A relative to the width and/or breadth of the plasma current passing through the first ports 235A, or the width and/or breadth of the plasma current may be narrowed or lessened as it enters and passes through the second ports 236A and first ports 235A.

### Showerhead Assembly

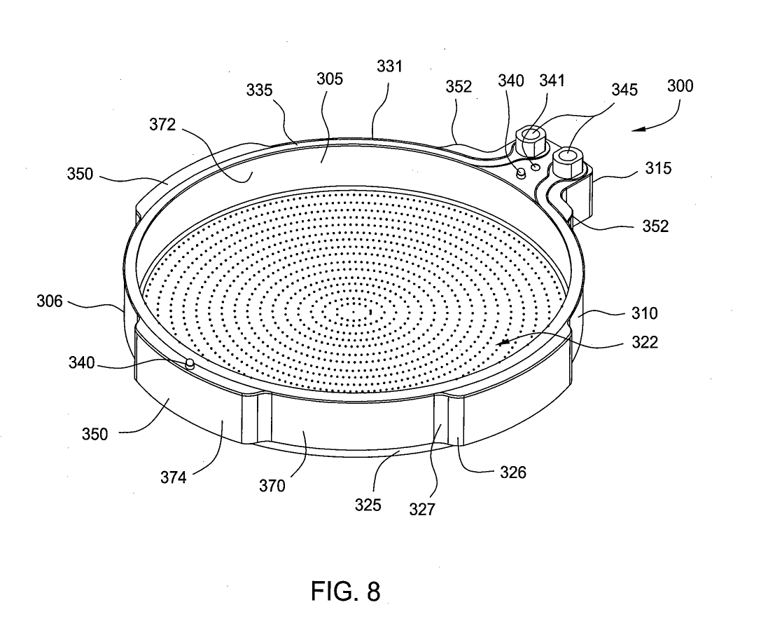

FIG. 8 is an isometric view of one embodiment of a gas distribution plate or showerhead 300. The showerhead 300 generally includes a circular member 305 having a recessed area 322 to define a wall 306. The recessed area 322 includes a perforated plate 320 disposed on an inside diameter 372 of the wall 306 or circular member 305. The circular member 305 or wall 306 includes the inside diameter 372 and a first outside diameter 370 to define an upper edge 331. A fluid channel 335 may be coupled to, integral to, or at least partially formed in, the upper edge 331. The fluid channel 335 is in communication with ports 345 that may function as an inlet and outlet for a heat transfer fluid, such as a cooling fluid. In one embodiment, the fluid channel 335 and port 345 form a separate element that is welded to the upper edge 331 of the circular member 305 or wall 306. The ports 345 are disposed on a mounting portion 315 coupled to a portion of the first outside diameter of the circular member 305 or wall 306.

In one embodiment, the first outside diameter 370 includes one or more shoulder sections 350. An outer surface of the shoulder sections 350 may include a radius or arcuate region that defines a second outer diameter that is greater than the first outside diameter. Each shoulder section 350 may be disposed at about 90° intervals about the circular member 305 or wall 306. In one embodiment, each shoulder section 350 includes a transitioned coupling with the circular member 305 or wall 306 that includes a curved portion, such as a convex portion 326 and/or a concave portion 327. Alternatively, the coupling may include an angled or straight-line transition to the circular member 305 or wall 306. In one embodiment, each of the shoulder sections 350 include coolant channels (not shown) in communication with the fluid channel 335 for flowing a coolant therein. The area of the circular member 305 or wall 306 having the mounting portion 315 coupled thereto may include partial shoulder sections 352 that are portions of the shoulder sections 350 as described above.

In one embodiment, the upper edge 331 of the circular member 305 or wall 306 one or more pins 340 extending therefrom that may be indexing pins to facilitate alignment of the showerhead 300 relative to the chamber 1. The mounting portion 315 may also include an aperture 341 adapted to receive a fastener, such as a screw or bolt, to facilitate coupling of the showerhead 300 to the chamber 1. In one embodiment, the aperture is a blind hole that includes female threads adapted to receive a bolt or screw.

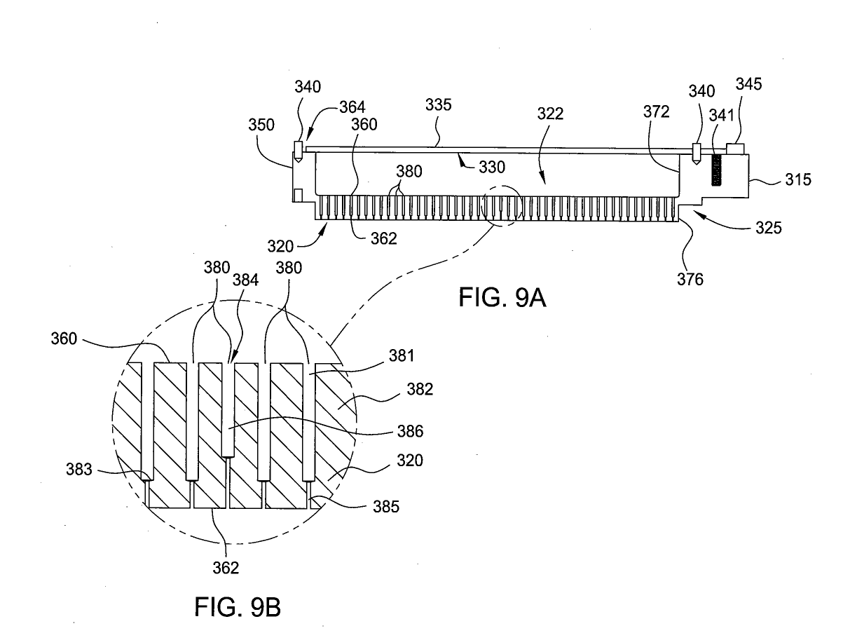

FIG. 9A is a cross-sectional side view of the showerhead 300 of FIG. 8. The showerhead 300 includes a first side 364 having a recessed area 322 formed therein to define a substantially planar inlet side or first side 360 of the perforated plate 320. The perforated plate 320 has a plurality of orifices 380 formed from the first side 360 to a second side 362 to allow process gases to flow therethrough. The first outside diameter 370 (not shown in this view) or perimeter of the circular member 305 or wall 306 includes a chamfer 325 that defines a third outside diameter 376 around the perforated plate 320. The third outside diameter 376 is less than the first and second outside diameters 370, 374, and may be substantially equal to the inside diameter 372. In one embodiment, the perforated plate 320 includes a third outside diameter that is substantially equal to the inside diameter 372 of the circular member 305 or wall 306.

FIG. 9B is an exploded cross-sectional view of a portion of the perforated plate 320 shown in FIG. 9A. The perforated plate 320 includes a body 382 having a plurality of orifices 380 formed therein. Each of the plurality of orifices 380 include a first opening 381 having a first diameter, a second opening 385 in fluid communication with the first opening 381 having a second diameter, and a tapered portion 383 therebetween. In one embodiment, the first opening 381 is disposed in the first side 360 of the perforated plate 320 and the second opening 385 is disposed in the second side 362 of the perforated plate 320. In one embodiment, the first opening 381 includes a diameter that is greater than the diameter of the second opening 385.

The depth, spacing, and/or diameters of the first and second openings 381, 385 may be substantially equal or include varying depths, spacing, and/or diameters. In one embodiment, one of the plurality of orifices 380 located in a substantial geometric center of the perforated plate 320, depicted as center opening 384, includes a first opening 386 having a depth that is less than first openings 381 in the remainder of the plurality of orifices 380. Alternatively or additionally, the spacing between the center opening 384 and immediately adjacent and surrounding orifices 380 may be closer than the spacing of other orifices 380. For example, if a circular or “bolt-center” pattern is used for the plurality of orifices 380, the distance, measured radially, between adjacent orifices may be a substantially equal or a include a substantially equal progression with the exception of the radial distance between the center opening 384 and the first or innermost circle of orifices 380, which may comprise a smaller distance than the remainder of the plurality of orifices. In some embodiments, the depths of the first openings 381 may be alternated, wherein one row or circle, depending on the pattern, may include first openings having one depth, and a second row or circle may include a different depth in the first opening 381. Alternatively, alternating orifices 380 along a specific row or circle in a pattern may include different depths and different diameters.

The pattern of the plurality of orifices 380 may include any pattern adapted to facilitate enhanced distribution and flow of process gases. Patterns may include circular patterns, triangular patterns, rectangular patterns, and any other suitable pattern. The showerhead 300 may be made of a process resistant material, preferably a conductive material, such as aluminum, which may be anodized, non-anodized, or otherwise include a coating.

### Substrate Support Assembly

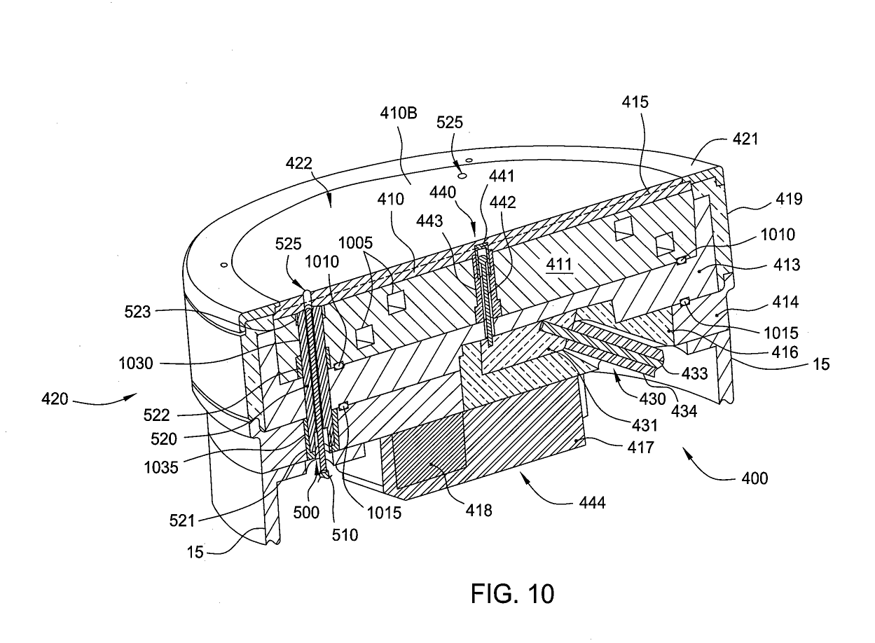

FIG. 10 is an isometric cross-sectional view of one embodiment of a substrate support assembly 400. The substrate support assembly 400 generally contains an electrostatic chuck 422, a shadow ring 421, a cylindrical insulator 419, a support insulator 413, a cathode base 414, an electrical connection assembly 440, a lift pin assembly 500, and a cooling assembly 444. The electrostatic chuck 422 generally contains a puck 410 and a metal layer 411. The puck 410 includes an embedded electrode 415 that may operate as a cathode within the electrostatic chuck 422. The embedded electrode 415 may be made of a metallic material, such as molybdenum, and may be formed as a perforated plate or a mesh material.

In one embodiment, the puck 410 and the metal layer 411 are bonded together at an interface 412 to form a single solid component that can support the puck 410 and enhance the transfer of heat between the two components. In one embodiment, the puck 410 is bonded to the metal layer 411 using an organic polymeric material. In another embodiment, the puck 410 is bonded to the metal layer 411 using a thermally conductive polymeric material, such as an epoxy material. In another embodiment, the puck 410 is bonded to the metal layer 411 using a metal braze or solder material. The puck 410 is made of an insulative or semi-insulative material, such as aluminum nitride (AlN) or aluminum oxide (Al₂O₃), which may be doped with other materials to modify electrical and thermal properties of the material, and the metal layer 411 is made of a metal having a high thermal conductivity, such as aluminum. In this embodiment, the substrate support assembly 400 is configured as a substrate contact-cooling electrostatic chuck. An example of a substrate contact-cooling electrostatic chuck may be found in U.S. patent application Ser. No. 10/929,104, filed Aug. 26, 2004, which published as United States Patent Publication No. 2006/0043065 on Mar. 2, 2006, which is incorporated by reference in it's entirety.

The metal layer 411 may contain one or more fluid channels 1005 that are coupled to the cooling assembly 444 that is connected to the cathode base 414. The cooling assembly 444 generally contains a coupling block 418 that has two or more ports (not shown) that are connected to the one or more fluid channels 1005 formed in the metal layer 411. During operation, a fluid, such as a gas, deionized water, or a GALDEN® fluid, is delivered through the coupling block 418 and the fluid channels 1005 to control the temperature of a substrate (not shown for clarity) positioned on the substrate supporting surface 410B of the puck 410 during processing. The coupling block 418 may be electrically or thermally insulated from the outside environment by use of an insulator 417, which may be formed from a plastic or a ceramic material.

The electrical connection assembly 440 generally includes a high voltage lead 442, a jacketed input lead 430, a connection block 431, a high voltage insulator 416, and a dielectric plug 443. In use, the jacketed input lead 430, which is in electrical communication with RF power source 405A (FIG. 1) and/or DC power source 406 (FIG. 1), is inserted and electrically connected to the connection block 431. The connection block 431, which is isolated from the cathode base 414 by the high voltage insulator 416, delivers the power from the RF power source 405A and/or DC power source 406 to the high voltage lead 442 that is electrically connected to the embedded electrode 415 positioned within the puck 410 through a receptacle 441. In one embodiment, the receptacle 441 is brazed, bonded, and/or otherwise attached to the embedded electrode 415 to form a good RF and electrical connection between the embedded electrode 415 and the receptacle 441. The high voltage lead 442 is electrically isolated from the metal layer 411 by use of the dielectric plug 443, which may be made of a dielectric material, such as polytetrafluoroethylene (PTFE), for example a TEFLON® material, or other suitable dielectric material.

The connection block 431, the high voltage lead 442, and the jacketed input lead 430 may formed from a conductive material, for example, a metal, such as brass, copper, or other suitable materials. The jacketed input lead 430 may include a center plug 433 made of a conductive material, such as brass, copper, or other conductive materials, and at least partially surrounded in a RF conductor jacket 434. In some cases it may be desirable to coat one or more of the electrical connection assembly 440 components with gold, silver, or other coating that promotes enhanced electrical contact between the mating parts.

In one embodiment, the electrostatic chuck 422, which contains the puck 410 and metal layer 411, is isolated from the grounded cathode base 414 by use of the support insulator 413. The support insulator 413 thus electrically and thermally isolates the electrostatic chuck 422 from ground. Generally, the support insulator 413 is made of a material that is capable of withstanding high RF bias powers and RF bias voltage levels without allowing arcing to occur or allowing its dielectric properties to degrade over time. In one embodiment, the support insulator 413 is made of a polymeric material or a ceramic material. Preferably, the support insulator 413 is made of an inexpensive polymeric material, such as a polycarbonate material, which will reduce the replacement part cost and the cost of the substrate support assembly 400, and thus improve its cost of ownership (CoO). In one embodiment, as shown in FIG. 10, the metal layer 411 is disposed within a feature formed within support insulator 413 to improve electrical isolation between the cathode base 414 and the embedded electrode 415.

To further isolate the puck 410 and metal layer 411 and to prevent arcing from occurring between these components and other components within the plasma chamber 1, a cylindrical insulator 419 and shadow ring 421 are used. In one embodiment, the cylindrical insulator 419 is formed so that it covers a support insulator 413 and circumscribes the electrostatic chuck 422 to minimize arcing between the electrostatic chuck 422 and various grounded components, such as the cathode base 414, when one or more of the components within the electrostatic chuck 422 are RF or DC biased during processing. The cylindrical insulator 419 generally may be formed from a dielectric material, such as a ceramic material (e.g., aluminum oxide), that can withstand exposure to the plasma formed in the processing region 25. In one embodiment, the shadow ring 421 is formed so that it covers a portion of the puck 410 and the support insulator 413 to minimize the chance of arcing occurring between the electrostatic chuck 422 components and other grounded components within the chamber. The shadow ring 421 is generally formed from a dielectric material, such as a ceramic material (e.g., aluminum oxide), that can withstand exposure to the plasma formed in the processing region 25.

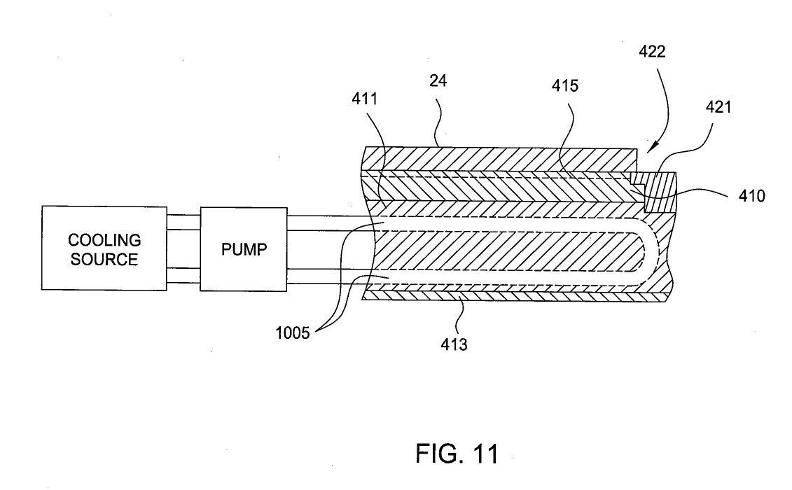

FIG. 11 is a partial cross sectional view of the electrostatic chuck 422 of FIG. 10 having a substrate 24 thereon. As shown, the edge of the substrate 24 will generally overhang the upper surface of the puck 410 and a portion of the shadow ring 421 is positioned to shield the upper surface of the puck from the plasma in the processing region 25. The shadow ring 421 may be made of a process compatible material, which includes silicon, silicon carbide, quartz, alumina, aluminum nitride, and other process compatible materials. Also shown in FIG. 11 are fluid channels 1005, which are in communication with a coolant source and a pump.

Referring again to FIG. 10, in one embodiment, an o-ring seal 1010 is placed between the metal layer 411 and the support insulator 413 to facilitate a vacuum seal and isolation of the processing region 25 from ambient atmosphere. The vacuum seal thus prevents atmospheric leakage into the processing region 25 when the chamber 1 is evacuated to a pressure below atmospheric pressure by the pump 40. One or more fluid o-ring seals (not shown) may also be positioned around the ports (not shown) that are used to connect the coupling block 418 to the one or more fluid channels 1005 to prevent leakage of a heat exchanging fluid that is flowing therein. The fluid o-ring seals (not shown) may be positioned between the metal layer 411 and the support insulator 413, and the support insulator 413 and the cathode base 414.

The cathode base 414 is used to support the electrostatic chuck 422 and support insulator 413 and is generally connected and sealed to the chamber bottom 15. The cathode base 414 is generally formed from an electrically and thermally conductive material, such as a metal (e.g., aluminum or stainless steel). In one embodiment, an o-ring seal 1015 is placed between the cathode base 414 and the support insulator 413 to form a vacuum seal to prevent atmospheric leakage into the processing region 25 when the chamber 1 is evacuated.

The substrate support assembly 400 may also include three or more lift pin assemblies 500 (only one is shown in this view) that contains a lift pin 510, a lift pin guide 520, an upper bushing 522 and a lower bushing 521. The lift pins 510 in each of the three or more lift pin assemblies 500 are used to facilitate the transfer of a substrate to and from the substrate support surface 410B, and to and from a robot blade (not shown) by use of an actuator (not shown) that is coupled to the lift pins 510. In one embodiment, a lift pin guide 520 is disposed in an aperture 1030 formed in the support insulator 313 and an aperture 1035 formed in the cathode base 314, and the lift pin 510 is actuated in a vertical direction through a hole 525 formed in the puck 410. The lift pin guide 520 may be formed from a dielectric material, such as a ceramic material, a polymeric material, and combinations thereof, while the lift pin 510 may comprise a ceramic or metal material.

In general, the dimensions of the lift pin guide 520 and apertures 1030, 1035, such as an outer diameter of the lift pin guide 520 and the inner diameter of the apertures 1030, 1035 are formed in a manner that minimizes or eliminates gaps therebetween. For example, the inner diameter of the apertures 1030, 1035 and outer diameter of the lift pin guide 520 are held to tight tolerances to prevent RF leakage and arcing problems during processing.

An upper bushing 522 in each of the lift pin assemblies 500 are used to support and retain the lift pin guides 520 when they are inserted within apertures 1030, 1035. In one embodiment, the fit between outer diameter of the upper bushing 522 and the aperture formed in the metal layer 311, and the inner diameter of the upper bushing 522 and the lift pin guide 520 are sized so that lift pin guide 520 is snugly located within the holes formed in the metal layer 311. In one embodiment, the upper bushing 522 is used to form a vacuum seal and/or an electrical barrier that prevents leakage of RF through the substrate support assembly 400. The upper bushings 522 may be formed from a polymeric material, such as a TEFLON® material.

The lower bushing 521 in each of the lift pin assemblies 500 are used to assure that the lift pin guides 520 are in contact or in close proximity to a back surface of the puck 410 to prevent plasma or RF leakage into the substrate support assembly 400. In one embodiment, the outer diameter of the lower bushing 521 is threaded so that it can engage threads formed in a region of the cathode base 414 to urge the lift pin guides 520 upward against the puck 410. The lower bushing 521 may be formed from a polymeric material, such as a TEFLON® material, PEEK, or other suitable material (e.g., coated metal component).

Depending upon the process, the RF bias voltage applied to the embedded electrode 415 by the RF power source 405A (FIG. 1) may vary between about 500 volts and about 10,000 volts. Such large voltages can cause arcing within the substrate support assembly 400 that will distort the process conditions and affect the usable lifetime of one or more components in the substrate support assembly 400. In order to reliably supply large bias voltages to the embedded electrode 415 without arcing, voids within the chuck are filled with a dielectric filler material that have a high breakdown voltage, such as TEFLON® material, a REXOLITE® material (manufactured by C-Lec Plastics, Inc), or other suitable material (e.g., polymeric materials). To prevent arcing issues that may damage the various components found within the substrate support assembly 400 it may be desirable to insert a dielectric material within the gaps formed between one or more components disposed within the substrate support assembly 400. In one embodiment, it is desirable to insert a dielectric material 523, for example ceramic, a polymer, a polytetrafluoroethylene, and combinations thereof, within the gaps formed in the metal layer 411, the support insulator 413, the cathode base 414 and the lift pin guide 520. In one embodiment, the dielectric material may be in the form of a polytetrafluoroethylene tape, such as tape made of a TEFLON® material, within the gaps formed between the apertures formed in the metal layer 411, the support insulator 413, the cathode base 414 and the lift pin guide 520. The thickness or amount of dielectric material 523 required to close the gaps to prevent RF leakage, which primarily occurs along the surface of the parts, may vary based on the dimensional tolerances of the mating components. In one embodiment, the exterior surfaces of the metal layer 411 is coated with a dielectric material or is anodized to reduce the chance of arcing between components in the substrate support assembly 400 during processing. In one aspect, the surface of the metal layer 411 that contacts the interface 412 is not anodized or coated to promote conduction of heat between the puck 410 and the fluid channel 1005.

While the foregoing is directed to embodiments of the present invention, other and further embodiments of the invention may be devised without departing from the basic scope thereof, and the scope thereof is determined by the claims that follow.

1. A toroidal plasma source, comprising:
a first hollow conduit comprising a U shape and a rectangular cross-section;
a second hollow conduit comprising an M shape and a rectangular cross-section;
an opening disposed at opposing ends of each of the first and second hollow conduits; and
a coating disposed on an interior surface of each of the first and second hollow conduits.

2. The apparatus of claim 1, wherein each of the first and second hollow conduits include a slot in a sidewall of the conduit to provide access to the interior surface.

3. The apparatus of claim 2, wherein the slot in the first hollow conduit comprises a U shape.

4. The apparatus of claim 2, wherein the slot in the second hollow conduit comprises an M shape.

5. The apparatus of claim 1, further comprising:
a cover adapted to fasten to a sidewall of the conduit.

6. The apparatus of claim 1, wherein the coating comprises a yttrium material.

7. The apparatus of claim 1, wherein each of the first and second hollow conduits include a radio frequency antenna disposed on an outer surface thereof.

8. A plasma channeling apparatus, comprising:
a body having at least two channels disposed longitudinally therethrough, the at least two channels being separated by a wedge-shaped member; and
a coolant channel formed at least partially in a sidewall of the body.

9. The apparatus of claim 8, further comprising:
a flange portion coupled to the body.

10. The apparatus of claim 8, wherein the each of the at least two channels include a first opening at a first end of the body and a second opening at a second end of the body, and the area of the second opening is greater than the area of the first opening.

11. The apparatus of claim 8, wherein each of the at least two channels have an interior surface and yttrium coating disposed thereon.

12. A gas distribution plate, comprising:
a circular member having a first side and a second side;
a recessed portion formed in a central region of the first side to form an edge along a portion of the first side of the circular member, wherein the recessed portion includes a plurality of orifices that extend from the first side to the second side; and a mounting portion coupled to a perimeter of the circular member and extending radially therefrom.

13. The apparatus of claim 12, further comprising:
a coolant channel coupled to the edge; and
an inlet and an outlet coupled to the mounting portion.

14. The apparatus of claim 12, wherein the plurality of orifices includes one orifice in the substantial center of the recessed portion that has a first opening with a depth less than the depth of first openings in the remainder of the plurality of orifices.

15. The apparatus of claim 12, wherein the first side further comprises:
at least two indexing pins spaced approximately 180° apart from each other.

16. The apparatus of claim 12, wherein the perimeter of the circular member includes a plurality of shoulder sections, each shoulder section defining a portion of an arc and having an outside diameter greater than an outside diameter of the circular member.

17. A cathode assembly for a substrate support, comprising:
a body having:
a conductive upper layer;
a conductive lower layer; and
a dielectric material electrically separating the upper layer and the lower layer, wherein at least one opening is formed longitudinally through the body; and
one or more dielectric fillers disposed at locations within the body selected from the group consisting of: a first interface between the dielectric material and the upper layer; and a second interface between the dielectric material and the lower layer, and combinations thereof.

18. The apparatus of claim 17, wherein the dielectric fillers comprise a material from the group consisting of a ceramic, a polymer, a polytetrafluoroethylene, and combinations thereof.

19. The apparatus of claim 17, further comprising an insulating lift pin guide disposed in the at least one opening, wherein the insulating lift pin guide comprises a material from the group consisting of a ceramic, a polymer, a polytetrafluoroethylene, and combinations thereof.

20. The apparatus of claim 17, wherein the body includes at least one coolant channel formed therein.

21. The apparatus of claim 17, wherein the upper conductive layer includes a puck having an embedded electrode.

22. The apparatus of claim 21, wherein the electrode comprises plural electrically separated electrodes occupying respective radial zones in the upper conductive layer.

23. The apparatus of claim 21, wherein the upper conductive layer is coupled to the puck using a polymeric material.
